(19) United States
(12) Patent Application Publication
(10) Pub. No.: US 2013/0044422 A1
(43) Pub. Date: Feb. 21, 2013

(54) ELECTRONIC DEVICE AND HINGE ASSEMBLY APPLIED TO THE ELECTRONIC DEVICE

(71) Applicants: JIAN LI, Shenzhen City (CN); JIN-XIN WANG, Shenzhen City (CN); TANG LI, Shenzhen City (CN)

(72) Inventors: JIAN LI, Shenzhen City (CN); JIN-XIN WANG, Shenzhen City (CN); TANG LI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD ., Shenzhen City (CN)

(21) Appl. No.: 13/525,526

(22) Filed: Jun. 18, 2012

(30) Foreign Application Priority Data
Aug. 15, 2011 (CN) 201110232869.5

(51) Int. Cl. E05D 7/00; G06F 1/16; H05K 5/03

(52) U.S. Cl. 361/679.08; 16/364; 361/679.01

(57) ABSTRACT

An electronic device includes a main body, a hinge assembly, and a flip cover. The hinge assembly includes a sliding rail mounted to the main body, a sliding base slidably assembled with the sliding rail, and a pivotal shaft. The pivotal shaft is rotatably and adjustably hinged to the sliding base. The flip cover is fixed to the pivotal shaft. The flip cover is capable of being rotated and slid relative to the main body via the hinge assembly, thereby enabling a plurality of configurations for the flip cover under a plurality of usage or turn-on states.

### BACKGROUND

1. Technical Field

The present disclosure generally relates to hinges and, in particular, a hinge assembly applied to the electronic device.

2. Description of Related Art

Touch panel computers are widely used. However, the commonly-used touch panel computer always have poor typing performance. Thus, there always requires to use an external keyboard for facilitating the user to type in letters and specifically control the touch panel computer. In addition, in order to obtain a proper viewing angle of the touch panel computer, there needs an external support mechanism for supporting the touch panel computer and adjusting the view angle of the touch panel computer. However, the existing external keyboard and the external support mechanism both occupy a large volume with complicated structures, and are hard to assemble and inconvenient to carry.

Therefore, there is room for improvement within the art.

### BRIEF DESCRIPTION OF THE DRAWINGS

The components in the drawings are not necessarily drawn to scale, the emphasis instead being placed upon clearly illustrating the principles of the present disclosure.

FIG. 1 shows an isometric view of an embodiment of an electronic device, in an unused (turn-off) state.

FIG. 2 shows an isometric view of the electronic device of FIG. 1, in a first turn-on state.

FIG. 3 shows an exploded, isometric view of the electronic device of FIG. 2, in which the electronic device includes a main body, a flip cover, and a hinge assembly adjustably connecting the flip cover to the main body.

FIG. 4 shows an exploded, isometric view of a first embodiment of the hinge assembly of the electronic device of FIG. 3.

FIG. 5 shows a second turn-on state of the electronic device of FIG. 1.

FIG. 6 shows a third turn-on state of the electronic device of FIG. 1.

FIG. 7 shows an exploded, isometric view of a second embodiment of the hinge assembly of the electronic device of FIG. 3.

### DETAILED DESCRIPTION

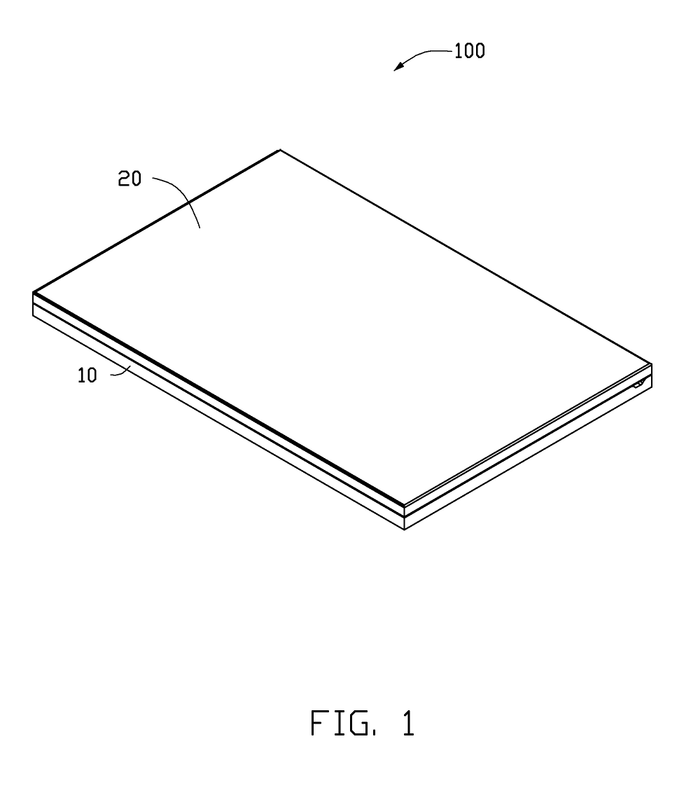

FIGS. 1 through 3, show an embodiment of an electronic device 100 including a main body 10, a flip cover 20, and two hinge assemblies 30. The main body 10 defines a keyboard area 104. The flip cover 20 has a display screen 21. The flip cover 20 is rotatably and slidably mounted to the main body 10 via the two hinge assemblies 30. The flip cover 20 may be rotated relative to the main body 10 for adjusting a proper viewing angle of the display screen 21 of the flip cover 20, and is also capable of sliding relative to the main body 10 for exposing the keyboard area 104 of the main body 10. In the illustrated embedment, the display screen 21 is a touch screen. The flip cover 20 is a touch panel computer. The number of the hinge assemblies 30 is not limited to two, and it may also be one or more than two, according to the actual needs.

The main body 10 is substantially rectangular, and includes a top operating surface 101, a front edge surface 102, and a rear edge surface 103 opposite to the front edge surface 102. The keyboard area 104 is formed on the top operating surface 101, and positioned adjacent to the front edge surface 102. Two receiving slots 105 are parallely defined in the top operating surface 101 of the main body 10, along a direction substantially perpendicular to the front and rear edge surfaces 102, 103, and are positioned opposite and adjacent to two ends of the keyboard area 104. In the illustrated embodiment, a cross-section of each receiving slot 105 is substantially an inverted T-shape. One end of each receiving slot 105 communicates with the rear edge surface 103. The number of the receiving slots 105 is equal to the number of hinge assemblies 30.

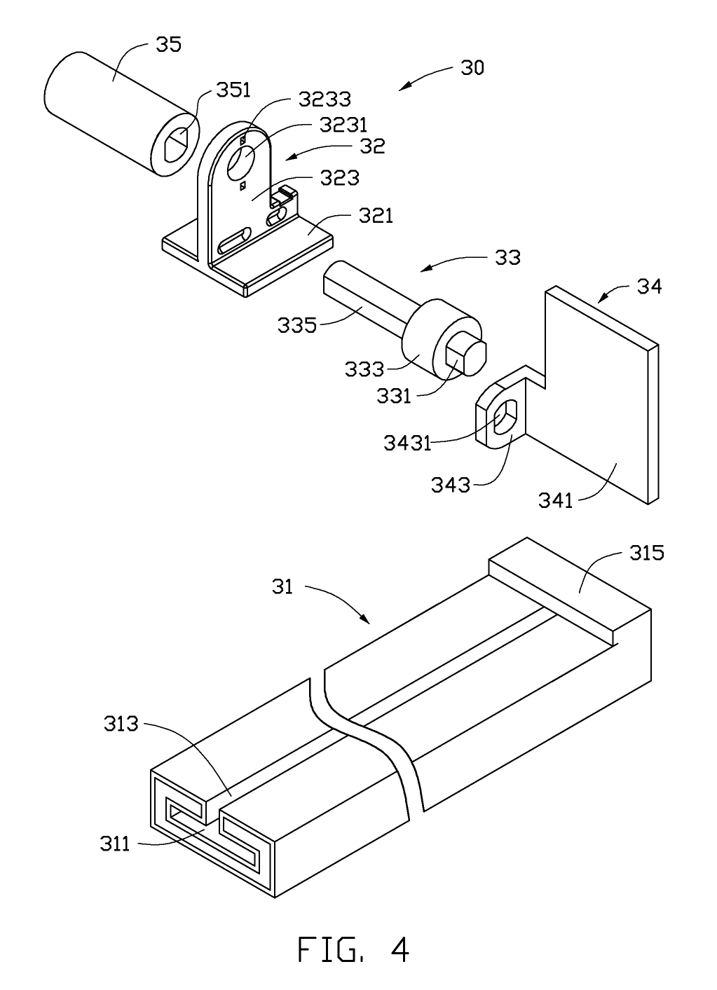

FIG. 4 shows that the two hinge assemblies 30 are assembled parallel into the two receiving slots 105 of the main body 10, and are further rotatably assembled with the flip cover 20. Each hinge assembly 30 includes a sliding rail 31, a sliding base 32, a pivotal shaft 33, a connecting member 34, and a shaft sleeve 35. The sliding rail 31 is substantially rectangular and is assembled within the receiving slot 105 of the main body 10. A stop block 315 is formed on a top surface of a first end of the sliding rail 31. A guiding slot 311 is defined in the sliding rail 31 longitudinally, to be extending from a cross-section of a second end of the sliding rail 31 toward the opposite first end of the sliding rail 31. A sliding slot 313 is defined through the top surface of the sliding rail 31 longitudinally, to be communicating with the corresponding guiding slot 311. In the illustrated embodiment, the sliding rail 31 is made by insert molding technology. In other embodiments, the sliding rail 31 can also be integrally-formed with the main body 10.

The sliding base 32 is a substantially T-shaped body, and includes a guiding portion 321 and a support portion 323 perpendicularly formed on a substantially middle portion of the guiding portion 321. The sliding base 32 is slidably assembled with the sliding rail 31, along with the guiding portion 321 of the sliding base 32 slidably engaging into the guiding slot 311 of the sliding rail 31, and the support portion 323 passes through and partially exposes from the corresponding sliding slot 313 of the sliding rail 31. The support portion 323 defines a pivotal hole 3231 and two limiting slots 3233 positioned at two sides of the pivotal hole 3231.

The pivotal shaft 33 rotatably passes through the sliding base 32, and further fixes with the flip cover 20, thereby rotatably assembling the flip cover 20 to the sliding base 32. The pivotal shaft 33 includes a first shaft portion 331, a flange 333, and a second shaft portion 335 coaxially connecting together in that order. The flange 333 is substantially disk shaped, and is coaxially positioned between the first shaft portion 331 and the second shaft portion 335. The second shaft portion 335 has a diameter substantially the same as that of the pivotal hole 3231 of the sliding base 32, and is capable of rotatably passing through the pivotal hole 3231 of the sliding base 32. The flange 333 resists against the support portion 323 for connecting the pivotal shaft 33 with the mounted flip cover 20 to be configured at a preset angle, as in use. An end surface of the flange 333 facing toward the corresponding support portion 323 forms an elastic protrusion (not shown) for latching with the corresponding limiting slots 3233 of the support portion 323.

The connecting member 34 and the shaft sleeve 35 are fixedly mounted to two ends of the pivotal shaft 33, respectively. In the illustrated embodiment, the connecting member 34 is a substantially L-shaped plate, and includes a first connecting portion 341 and a second connecting portion 343 bending from one side of the first connecting portion 341. The second connecting portion 343 defines a second shaft hole 3431 corresponding to the first shaft portion 331. The shaft sleeve 35 defines a third shaft hole 351 having a shape corresponding to that of the second shaft portion 335 such that the shaft sleeve 35 is securely sleeved on the second shaft portion 335.

When assembling the hinge assembly 30, the guiding portion 321 of the sliding base 32 aligns with and slidably engages into the guiding slot 311 of the sliding rail 31, the support portion 323 passes through the corresponding sliding slot 313 and is partially exposed from the top surface of the sliding rail 31. The second shaft portion 335 of the pivotal shaft 33 rotatably passes through the pivotal hole 3231 of the sliding base 32 and is fixed into the third shaft hole 351 of the shaft sleeve 35, such that, the pivotal shaft 33 is rotatably assembled to the sliding base 32. The flange 333 resists against the support portion 323. The second connecting portion 343 of the connecting member 34 is fixed to the first shaft portion 331 of the pivotal shaft 33, together with the first shaft portion 331 securely engaged into the second shaft hole 3431, to finish the assembly of the hinge assembly 30. As in use, the sliding base 32 together with the pivotal shaft 33, the connecting member 34 and the shaft sleeve 35, is capable of sliding relative to the sliding rail 31, the pivot shaft 33 together with the connecting member 34 and the shaft sleeve 35, is rotated relative to the sliding base 32

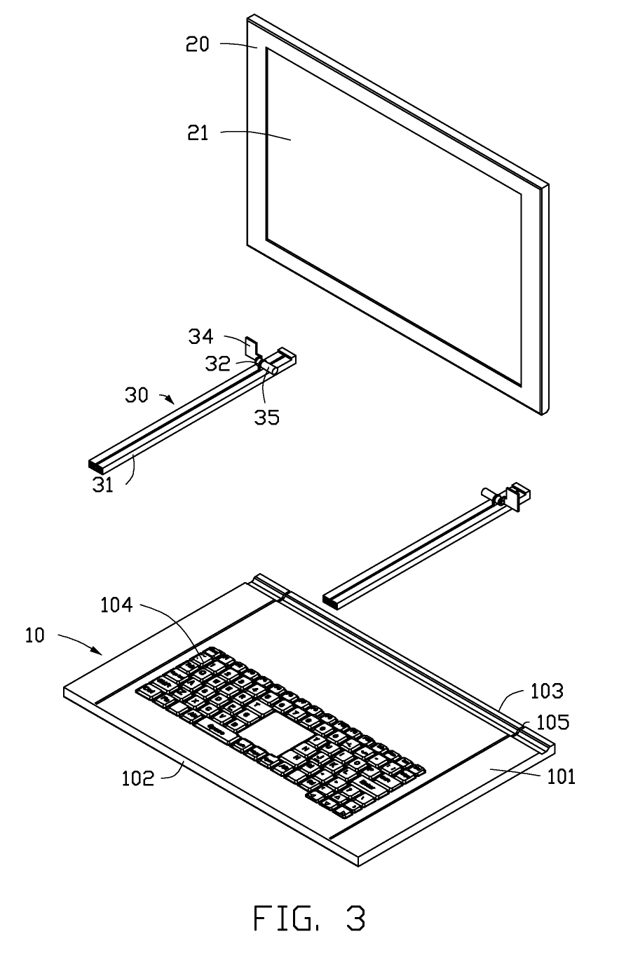

FIG. 3 shows again, when assembling the electronic device 100, the two sliding rails 31 of the two assembled hinge assemblies 30 are engaged into and received within the two receiving slots 105 of the main body 10. The support portion 323 of each hinge assembly 30 is partially exposed from the corresponding receiving slot 105, together with the connecting member 34 and the shaft sleeve 35. The flip cover 20 is finally fixed to the two connecting members 34 to finish the assembly of the electronic device 100.

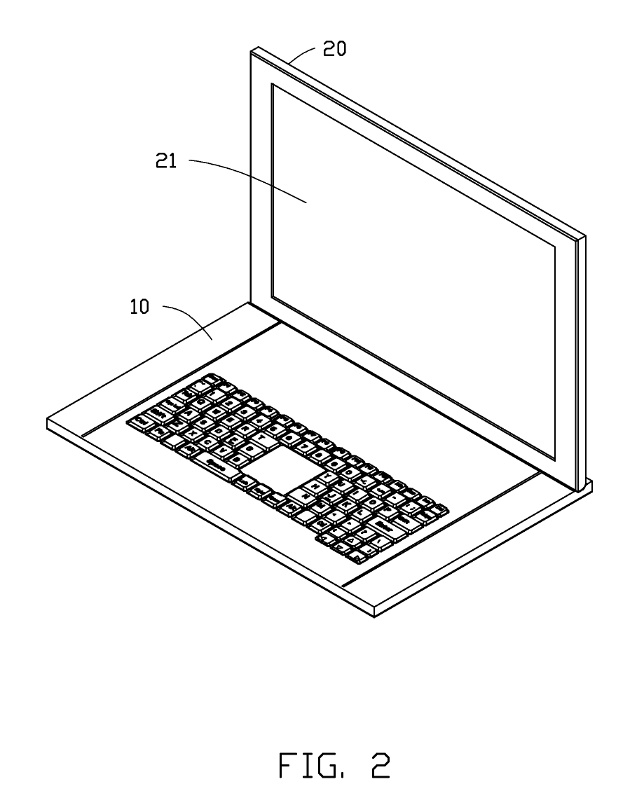

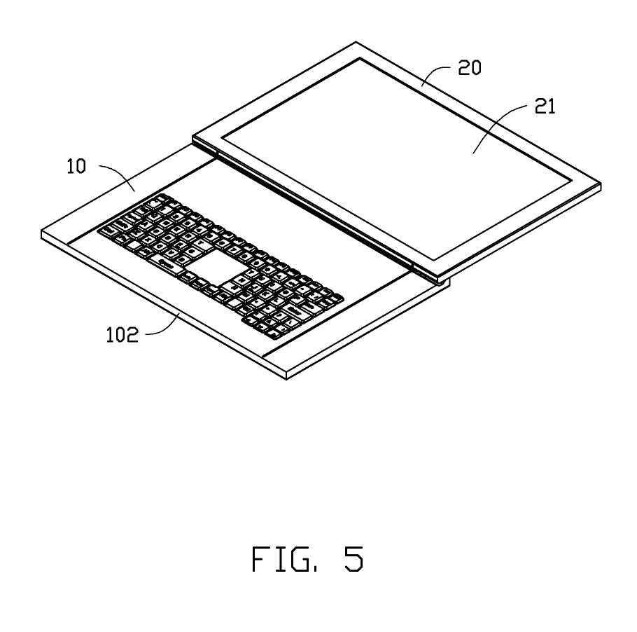

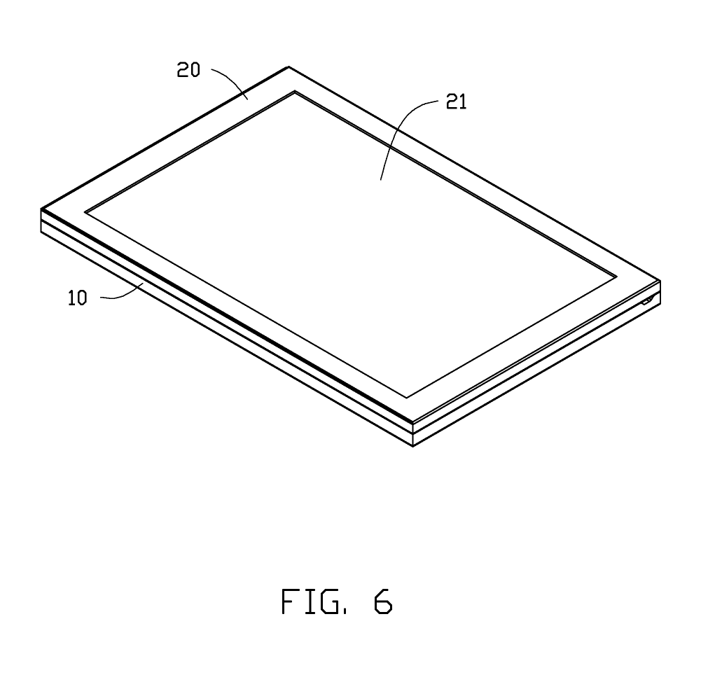

FIG. 1 shows the electronic device 100 in an un-used/turn-off state, the flip cover 20 is folded and covered over the main body 10, with the display screen 21 facing against the corresponding top operating surface 101 of the main body 10. Also FIG. 2, shows when using the electronic device 100, the flip cover 20 is capable of being rotated away from the front edge surface 102 of the main body 10 to expose the keyboard area 104. In addition, the display screen 21 of the flip cover 20 remains at a proper viewing angle relative to the main body 10, such that, a user can control the electronic device 100 by operating the keyboard area 104 or directly touching the display screen 21. Also FIG. 5 shows a second usage or turn-on state of the electronic device 100, in which the flip cover 20 is capable of being further rotated to form a substantially 180 degrees with the main body 10; namely, the flip cover 20 is configured substantially parallel to the main body 10. Also FIG. 6, shows a third usage or turn-on state of the electronic device 100, in which the flip cover 20 is pushed to slide toward the front edge surface 102 side of the main body 10, and finally overlaps on the main body 10, to form a configuration with the display screen 21 facing away from the main body 10.

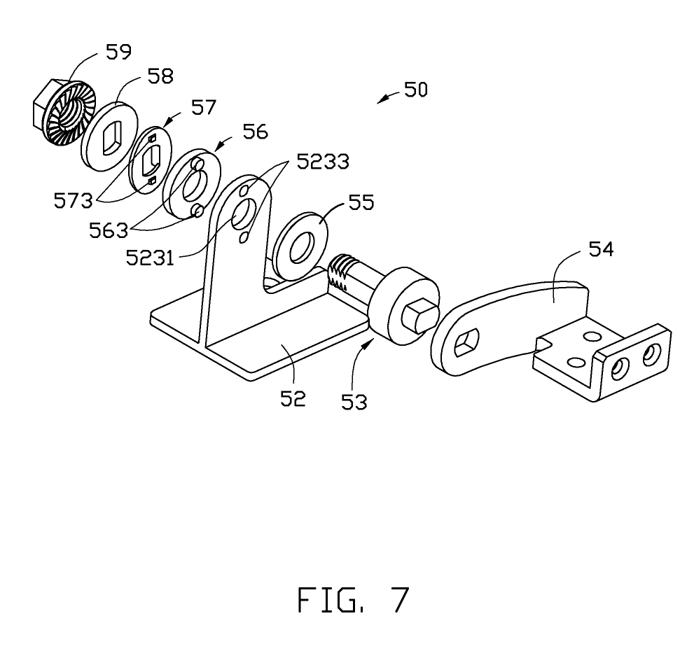

FIG. 7 shows an exploded isometric view of a second embodiment of the hinge assembly 50. The hinge assembly 50 includes a sliding base 52, a pivotal shaft 53, a connecting member 54, a friction washer 55, a limiting washer 56, a retaining washer 57, a sleeving washer 58, and a fastener 59. The sliding base 52 has substantially the same shape as that of the sliding base 32 of the first embodiment. The sliding base 52 defines a pivotal hole 5231 and two limiting holes 5233 positioned at two sides of the pivotal hole 5231. The friction washer 55, the limiting washer 56, the retaining washer 57, and the sleeving washer 58 are all disk-shaped and sleeved on the pivotal shaft 53 in that order. The limiting washer 56 forms two positioning posts 563 on a first end surface of the limiting washer 56, corresponding to the two limiting holes 5233 of the sliding base 52. Two engaging slots (not shown) are defined in a second end surface of the limiting washer 56. The retaining washer 57 forms two retaining blocks 573 on one end surface of the retaining washer 57 corresponding to the two engaging slots of the limiting washer 56.

When assembling the hinge assembly 50, a first end of the pivotal shaft 53 passes through the friction washer 55, the pivotal hole 5231 of the sliding base 52, the limiting washer 56, the retaining washer 57, and the sleeving washer 58 in that order, and is finally fixed by the fastener 59. The two positioning posts 563 of the limiting washer 56 are engaged into the two limiting holes 5233 of the sliding base 52, such that, the limiting washer 56 is non-rotatable relative to the sliding base 52. The retaining washer 57 together with the sleeving washer 58 is non-rotatably sleeved on the pivotal shaft 53, with the two retaining blocks 573 latched into the corresponding two engaging slots of the limiting washer 56. The connecting member 54 is finally fixed to a second end of the pivotal shaft 53.

In use, when the connecting member 54 is rotated relative to the sliding base 52, the pivotal shaft 53 is driven to rotate simultaneously, and thus, the retaining washer 57, the sleeving washer 58 and the fastener 59, together with the pivotal shaft 53, are also driven to rotate. However, the limiting washer 56 together with the sliding base 52 is non-rotatable, and thus, the two retaining blocks 573 of the retaining washer 57 are forced to disengage away from the corresponding two engaging slots of the limiting washer 56. In addition, the retaining blocks 573 elastically resist against the second end surface of the limiting washer 56, thereby retaining the connecting member 54 to stop at a proper position.

Finally, while various embodiments have been described and illustrated, the disclosure is not to be construed as being limited thereto. Various modifications can be made to the embodiments by those skilled in the art without departing from the true spirit and scope of the disclosure as defined by the appended claims.

What is claimed is:

1. An electronic device, comprising:
a main body;
a hinge assembly comprising:
a sliding rail mounted to the main body;
a sliding base slidably assembled with the sliding rail; and
a pivotal shaft rotatably hinged to the sliding base; and
a flip cover fixed to the pivotal shaft; wherein, the flip cover is capable of rotating and sliding relative to the main body via the hinge assembly, thereby enabling a plurality of configurations for the flip cover under a plurality of turn-on states.

2. The electronic device of claim 1, wherein, the main body comprises a top operating surface and defines a receiving slot in the top operating surface, the sliding rail is assembled within the receiving slot of the main body; the sliding base is partially exposed from the top operating surface and rotatably assembled with the flip cover via the pivotal shaft.

3. The electronic device of claim 2, wherein the main body further comprises a keyboard area disposed on the top operating surface, a front edge surface, and a rear edge surface opposite to the front edge surface; the receiving slot is defined in the top operating surface along a direction substantially perpendicular to the front and rear edge surfaces; one end of the receiving slot communicates with the rear edge surface.

4. The electronic device of claim 3, wherein the sliding rail defines a sliding slot longitudinally to be communicating with a guiding slot, the sliding base comprises a guiding portion and a support portion formed on the guiding portion, the guiding portion is slidably engaged into the guiding slot and received within the sliding slot, the support portion is exposed from the top operating surface of the main body; the support portion defines a pivotal hole, the pivotal shaft rotatably passes through the pivotal hole and is fixed with the corresponding flip cover.

5. The electronic device of claim 4, wherein the support portion further defines two limiting slots positioned at two sides of the pivotal hole, the pivotal shaft comprises a first shaft portion, a flange, and a second shaft portion coaxially connecting together in that order, the first shaft portion is fixed with the flip cover, the second shaft portion passes through the pivotal hole and rotatably assembled with the support portion; the flange resists against the support portion for connecting the pivotal shaft together with the flip cover to be configured at a preset angle; an end surface of the flange facing toward the corresponding support portion forms two elastic protrusions for latching with the corresponding limiting slots.

6. The electronic device of claim 5, wherein the hinge assembly further comprises a shaft sleeve defining a shaft hole corresponding to the second shaft portion, such that the shaft sleeve is fixedly sleeved on the second shaft portion.

7. The electronic device of claim 5, further comprising a connecting member fixed to the first shaft portion of the pivotal shaft, wherein the connecting member comprises a first connecting portion and a second connecting portion bending from one side of the first connecting portion, the second connecting portion defines a second shaft hole corresponding to the first shaft portion.

8. An electronic device, comprising:
a main body comprising a top operating surface and defining two parallel receiving slots;
a flip cover; and
two hinge assemblies slidably mounted within the two receiving slots of the main body, and further rotatably connected with the flip cover, such that the flip cover is capable of rotating and sliding relative to the main body via the two hinge assemblies;
wherein, each hinge assembly comprises a sliding base and a pivotal shaft, the sliding base is slidably assembled into one corresponding receiving slot and partially exposed from the top operating surface of the main body; the pivotal shaft is rotatably hinged to the sliding base, and fixed with the flip cover.

9. The electronic device of claim 8, wherein the receiving slot is a substantially inverted T-shaped slot, the sliding base comprises a guiding portion and a support portion formed on the guiding portion, the guiding portion is slidably engaged into and received within a bottom of the receiving slot, the support portion is exposed from the top operating surface; the support portion defines a pivotal hole, and the pivotal shaft rotatably passes through the pivotal hole and is fixed with the corresponding flip cover.

10. The electronic device of claim 9, wherein the support portion further defines two limiting slots positioned at two sides of the pivotal hole, the pivotal shaft comprises a first shaft portion, a flange, and a second shaft portion coaxially connecting together in that order, the first shaft portion is fixed with the flip cover, the second shaft portion passes through the shaft hole and rotatably assembled with the support portion; the flange resists against the support portion for connecting the pivotal shaft together with the flip cover at a preset angle; an end surface of the flange facing toward the corresponding support portion forms two elastic protrusions for latching with the corresponding limiting slots.

11. The electronic device of claim 10, wherein the hinge assembly further comprises a shaft sleeve and a connecting member, the shaft sleeve is fixedly sleeved on the second shaft portion, and defines a third shaft hole corresponding to the second shaft portion; connecting member fixed to the first shaft portion of the pivotal shaft, the connecting comprises a first connecting portion and a second connecting portion bending from one side of the first connecting portion, the second connecting portion defines a second shaft hole corresponding to the first shaft portion.

12. The electronic device of claim 8, wherein the hinge assembly further comprises a connecting member, a limiting washer, a retaining washer, a sleeving washer, and a fastener, the sliding base defines a pivotal hole and two limiting holes positioned at two sides of the pivotal hole; a first end of the pivotal shaft passes through the pivotal hole, the limiting washer, the retaining washer, and the sleeving washer in that order, and is finally fixed with the fastener; a second end of the pivotal shaft is fixed to the connecting member; the limiting washer forms two positioning posts on a first end surface of the limiting washer and engaging into the corresponding two limiting holes of the sliding base; the retaining washer is non-rotatably sleeved on the pivotal shaft and latches with the limiting washer.

13. The electronic device of claim 12, wherein the main body further comprises a keyboard area disposed on the top operating surface, a front edge surface, and a rear edge surface opposite to the front edge surface; the two receiving slots are parallely defined in the top operating surface, along a direction substantially perpendicular to the front and rear edge surfaces, and are oppositely positioned adjacent to two ends of the keyboard area.

14. A hinge assembly comprising:
a sliding rail defining a guiding slot;
a sliding base slidably assembled with the sliding rail, and comprising a guiding portion and a support portion formed on the guiding portion; wherein, the guiding portion of the sliding base is slidably engaging into the guiding slot of the sliding rail, the support portion passes through and is partially exposed from the corresponding sliding slot of the sliding rail; the support portion defines a pivotal hole; and
a pivotal shaft rotatably passes through the pivotal hole and adjustably hinged to the support portion of the sliding base.

15. The hinge assembly of claim 14, wherein the sliding rail further comprises a stop block formed on a top surface of a first end of the sliding rail, the guiding slot is defined in the sliding rail longitudinally, to be extending from a cross-section of a second end of the sliding rail toward the opposite first end of the sliding rail.

16. The hinge assembly of claim 15, wherein the support portion further defines two limiting slots positioned at two sides of the pivotal hole, the pivotal shaft comprises a first shaft portion, a flange, and a second shaft portion coaxially connecting together in that order, the second shaft portion passes through the shaft hole and rotatably assembled with the support portion; the flange resists against the support portion for connecting the pivotal shaft; an end surface of the flange facing toward the corresponding support portion forms two elastic protrusions for latching with the corresponding limiting slots.

17. The hinge assembly of claim 16, wherein further comprising a connecting member fixed to the first shaft portion of the pivotal shaft, the connecting member comprises a first connecting portion and a second connecting portion bending from one side of the first connecting portion, the second connecting portion defines a second shaft hole corresponding to the first shaft portion.

18. The hinge assembly of claim 14, wherein the hinge assembly further comprises a connecting member, a limiting washer, a retaining washer and a fastener, the sliding base defines a pivotal hole and two limiting holes positioned at two sides of the pivotal hole; a first end of the pivotal shaft passes through the pivotal hole, the limiting washer, the retaining washer in that order, and finally fixed with the fastener; a second end of the pivotal shaft is fixed to the connecting member; the limiting washer forms two positioning posts on a first end surface of the limiting washer and engaging into the corresponding two limiting holes of the sliding base; the retaining washer is non-rotatably sleeved on the pivotal shaft and latches with the limiting washer.
